(19) United States
(12) Patent Application Publication
(10) Pub. No.: US 2013/0134833 A1
(43) Pub. Date: May 30, 2013

(54) ULTRASONIC SENSOR AND METHOD FOR MANUFACTURING THE SAME

(71) Applicants: Boum Seock Kim, Gyunggi-do (KR); Jung Min Park, Gyunggi-do (KR); Eun Tae Park, Gyunggi-do (KR)

(72) Inventors: Boum Seock Kim, Gyunggi-do (KR); Jung Min Park, Gyunggi-do (KR); Eun Tae Park, Gyunggi-do (KR)

(73) Assignee: SAMSUNG ELECTRO-MECHANICS CO., LTD., Gyunggi-do (KR)

(21) Appl. No.: 13/360,680

(22) Filed: Jan. 28, 2012

(30) Foreign Application Priority Data
Nov. 24, 2011 (KR) 1020110123727

(51) Int. Cl. G10K 9/122; H05K 13/00

(52) U.S. Cl. 310/327; 29/25.35

(57) ABSTRACT

Disclosed herein are an ultrasonic sensor and a method of manufacturing the same. The ultrasonic sensor includes: a case having one end closed and the other end opened; a piezoelectric element fixedly coupled to one end of an inner portion of the case; a sound absorbing member coupled to an upper surface of the piezoelectric element so as to cover a portion of the piezoelectric element; a conductive member having one end connected to the piezoelectric element and the other end connected to the sound absorbing member; and a lead wire electrically coupled to the conductive member and the case.

### CROSS REFERENCE TO RELATED APPLICATION

This application claims the benefit of Korean Patent Application No. 10-2011-0123727, filed on Nov. 24, 2011, entitled “Ultrasonic Sensor and Method of Manufacturing the Same”, which is hereby incorporated by reference in its entirety into this application.

### BACKGROUND OF THE INVENTION

1. Technical Field

The present invention relates to an ultrasonic sensor and a method of manufacturing the same.

2. Description of the Related Art

In an ultrasonic sensor and a method of manufacturing the same according to the prior art, the ultrasonic sensor is configured to include a case, a piezoelectric element coupled to an inner portion of the case, a lead wire electrically connected to the case, and a lead wire electrically connected to the piezoelectric element.

Further, in the method of manufacturing the ultrasonic sensor, after the piezoelectric element is fixedly coupled to the inner portion of the case, one of the lead wires is fixedly coupled to an inner side surface of the case by a soldering process and another thereof is fixedly coupled to the piezoelectric element by the soldering process.

However, in the case of a scheme of coupling the lead wire to the piezoelectric element by the soldering process, thermal stress due to the soldering is locally applied to the piezoelectric element, such that unique piezoelectric characteristics of the piezoelectric element are deteriorated.

In addition, in the case of the method of manufacturing the ultrasonic sensor in which one of the lead wires is coupled to the case by the soldering process and another thereof is coupled to the piezoelectric element by the soldering process, since a worker directly performs the soldering process, a soldering region is non-uniform and automation of a manufacturing process is difficult.

### SUMMARY OF THE INVENTION

The present invention has been made in an effort to provide an ultrasonic sensor including a conductive member electrically connecting a lead wire and a piezoelectric element to each other without using a soldering process, and a method of manufacturing the same.

According to a preferred embodiment of the present invention, there is provided an ultrasonic sensor including: a case having one end closed and the other end opened; a piezoelectric element fixedly coupled to one end of an inner portion of the case; a sound absorbing member coupled to an upper surface of the piezoelectric element so as to cover a portion of the piezoelectric element; a conductive member having one end connected to the piezoelectric element and the other end connected to the sound absorbing member; and a lead wire electrically coupled to the conductive member and the case.

The conductive member may include: a contact part electrically connected to the upper surface of the piezoelectric element; and a lead wire connection part extended from the contact part and fixed to an upper portion of an outer peripheral surface of the sound absorbing member to thereby be electrically connected to the lead wire.

The lead wire connection part may include a fixing groove part formed in order to be electrically connected to the lead wire.

The conductive member may be formed of any one of a conductive wire, a conductive rubber, and a conductive film.

The sound absorbing member may have a cylindrical shape in which it includes: a hollow hole formed in order to open a portion of the upper surface of the piezoelectric element to the outside; and a fixing groove part formed in an outer peripheral surface thereof so as to fix the lead wire in order to electrically connect the lead wire and an inner side surface of the case to each other.

The case may include a reception groove formed in an inner side of the closed one end thereof so that the piezoelectric element is fixedly coupled thereto.

The lead wire may include: an anode (+) lead wire electrically coupled to the conductive member; and a cathode (−) lead wire electrically coupled to an inner side wall surface of the case.

The ultrasonic sensor may further include a filling member filled in the inner portion of the case in order to cover the piezoelectric element and the sound absorbing member from the outside and shield an ultrasonic wave generated from the piezoelectric element from moving toward the opened portion of the case.

According to another preferred embodiment of the present invention, there is provided a method of manufacturing an ultrasonic sensor, the method including: (a) fixedly coupling a piezoelectric element to an inner portion of a case having a reception groove formed at an inner side of a closed one end thereof; (b) coupling a cylindrical sound absorbing member having a fixing groove part formed in an outer peripheral surface thereof and a hollow hole formed in order to open a portion of an upper surface of the piezoelectric element to the upper surface of the piezoelectric element; (c) fixedly coupling a conductive member to upper surfaces of the piezoelectric element and the sound absorbing member; and (d) fixedly coupling a cathode (−) lead wire to the fixing groove part of the sound absorbing member and fixedly coupling an anode (+) lead wire to the conductive member.

The method may further include, after step (d), filling a filling member in the inner portion of the case in order to cover the piezoelectric element and the sound absorbing member from the outside and shield an ultrasonic wave generated from the piezoelectric element from moving toward the opened portion of the case.

### BRIEF DESCRIPTION OF THE DRAWINGS

FIG. 1 is a schematic coupling cross-sectional view of an ultrasonic sensor according to a preferred embodiment of the present invention;

FIGS. 2 and 3 are perspective views describing a method of manufacturing an ultrasonic sensor shown in FIG. 1; and

FIG. 4 is a perspective view schematically showing a state in which a sound absorbing member and a conductive member configuring the ultrasonic sensor shown in FIG. 1 are coupled to each other.

### DESCRIPTION OF THE PREFERRED EMBODIMENTS

Various objects, advantages and features of the invention will become apparent from the following description of embodiments with reference to the accompanying drawings. In the specification, in adding reference numerals to components throughout the drawings, it is to be noted that like reference numerals designate like components even though components are shown in different drawings. Further, terms used in the specification, ‘first’, ‘second’, etc. can be used to describe various components, but the components are not to be construed as being limited to the terms. The terms are only used to differentiate one component from other components. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

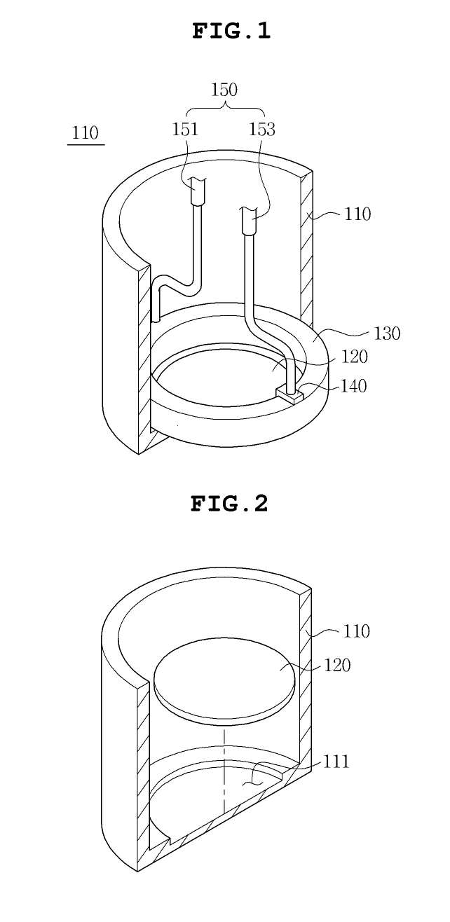

FIG. 1 is a schematic coupling cross-sectional view of an ultrasonic sensor according to a preferred embodiment of the present invention. As shown, the ultrasonic sensor 100 is configured to include a case 110, a piezoelectric element 120, a sound absorbing member 130, a conductive member 140, a lead wire 150, and a filling member (not shown).

The case 110 may have a cylindrical shape in which one end thereof is closed so that a bottom surface is formed and the other end thereof is opened.

In addition, the case includes a reception groove 111 formed in an inner side of the closed one end thereof at which the bottom surface is formed so that the piezoelectric element 120 is fixedly coupled thereto.

The piezoelectric element 120, which is repeatedly extended and contracted according to whether or not voltage is applied to thereby generate an ultrasonic wave, is fixedly coupled to the reception groove 111 of the case 110 by applying a conductive epoxy to a surface thereof facing the bottom surface of the case 110.

The sound absorbing member 130, which is to partially shield the ultrasonic wave generated from the piezoelectric element 120 from moving to the opened portion of the case 110, may have a cylindrical shape.

More specifically, the sound absorbing member 130 includes a hollow hole 131 opening a portion of an upper surface of the piezoelectric element 120 to the outside and a fixing groove part 133 fixing a cathode (−) lead wire 151 of the lead wire 150 to be described below.

In addition, the fixing groove part 133 has an opened surface formed in a direction in which it faces an inner side surface of the case 110.

Therefore, the cathode lead wire 151 is electrically connected to the inner side surface of the case 110.

The conductive member 140 has one end connected to the piezoelectric element 120 and the other end connected to the sound absorbing member 130 as shown in FIG. 4 schematically showing a state in which the sound absorbing member and the conductive member configuring the ultrasonic sensor are coupled to each other.

More specifically, the conductive member 140 includes a contact part 141 electrically connected to the upper surface of the piezoelectric element 120 and a lead wire connection part 143 extended from the contact part 141 and fixed to an upper portion of an outer peripheral surface of the sound absorbing member 130 to thereby be electrically connected to an anode (+) lead wire 153 of the lead wire 150 to be described below.

In addition, the lead wire connection part 143 includes a fixing groove part 155 formed in order to be electrically connected to the anode lead wire 133.

Further, the conductive member 140 may be formed of any one of a conductive wire, a conductive rubber, and a conductive film in order to electrically connect the anode lead wire 153 and the piezoelectric element 120 to each other.

Therefore, the piezoelectric element 120 and the anode lead wire 153 configuring the lead wire 150 are electrically connected to each other through the conductive member 140, and the cathode lead wire 151 is electrically connected to the inner side surface of the case 110, such that when power is applied to the piezoelectric element 120, the ultrasonic wave is generated.

The lead wire 150 may include the cathode lead wire 151 and the anode lead wire 153 as described above.

More specifically, the cathode lead wire 151 is fixedly coupled to the fixing groove part 133 having the opened surface formed in the direction in which the fixing groove part 133 faces the inner side surface of the case 110 to thereby be electrically connected to the inner side surface of the case 110.

In addition, the anode lead wire 153 is fixedly coupled to the conductive member 140 to thereby be electrically connected to the piezoelectric element 120.

The filling member (not shown) is filled in an inner portion of the case 110 in order to cover the piezoelectric element 120 and the sound absorbing member 130 from the outside.

Therefore, movement of the ultrasonic wave generated from the piezoelectric element 120 toward the opened portion of the case 110 is completely shielded.

Accordingly, it is possible to reduce an influence by unnecessary reverberation signals or vibration leakage of reception signals when the ultrasonic sensor 100 detects an external object.

FIGS. 2 to 4 are perspective views describing a method of manufacturing an ultrasonic sensor shown in FIG. 1.

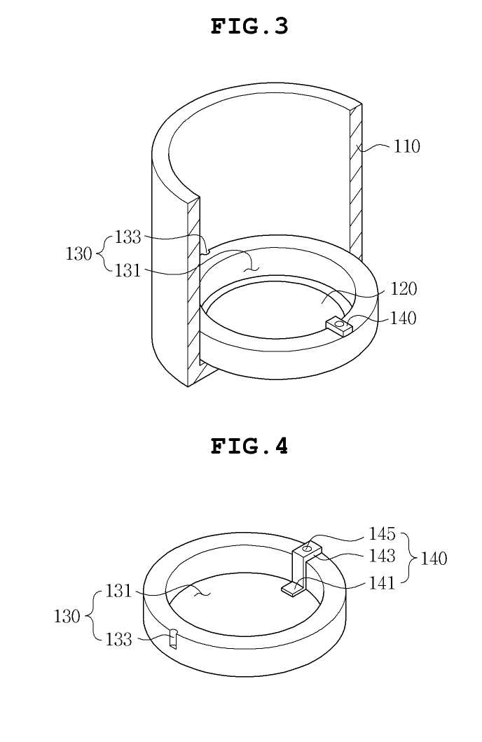

More specifically, FIG. 2 is a perspective view showing a state in which the case and the piezoelectric element are coupled to each other; and FIG. 3 is a perspective view showing a state in which the sound absorbing material and the conductive member are coupled to each other from FIG. 2. As shown, in the method of manufacturing an ultrasonic sensor according to the preferred embodiment of the present invention, first, (a) the piezoelectric element 120 to which the conductive epoxy is applied is fixedly coupled to the inner portion of the case 110 having the reception groove 111 formed at the inner side of the closed one end thereof.

Then, (b) the cylindrical sound absorbing member 130 having the fixing groove part 133 formed in the outer peripheral surface thereof and the hollow hole 131 formed in order to open a portion of the upper surface of the piezoelectric element 120 is coupled to the upper surface of the piezoelectric element 120.

Next, (c) the conductive member 140 is fixedly coupled to the upper surfaces of the piezoelectric element 120 and the sound absorbing member 130.

Thereafter, (d) the cathode (−) lead wire 151 is fixedly coupled to the fixing groove part 133 of the sound absorbing member 130, and the anode (+) lead wire 153 is fixedly coupled to the fixing groove part 133 of the conductive member 140.

Then, the filling member (not shown) for covering the piezoelectric element 120 and the sound absorbing member 130 from the outside and shielding the ultrasonic wave generated from the piezoelectric element 120 from moving toward the opened portion of the case 110 is filled in the inner portion of the case 110.

As set forth above, according to the preferred embodiments of the present invention, the lead wire and the piezoelectric element are electrically connected to each other using the conductive member, thereby making it possible to automate a process of manufacturing an ultrasonic sensor.

In addition, the lead wire and the piezoelectric element are electrically connected to each other by the conductive member without performing a soldering process that was performed in order to connect the lead wire and the piezoelectric element to each other according to the prior, thereby making it possible to constantly maintain design characteristics of the piezoelectric element.

Although the preferred embodiments of the present invention have been disclosed for illustrative purposes, they are for specifically explaining the present invention and thus an ultrasonic sensor and a method of manufacturing the same according to the present invention are not limited thereto, but those skilled in the art will appreciate that various modifications, additions and substitutions are possible, without departing from the scope and spirit of the invention as disclosed in the accompanying claims.

Accordingly, any and all modifications, variations or equivalent arrangements should be considered to be within the scope of the invention, and the detailed scope of the invention will be disclosed by the accompanying claims.

What is claimed is:

1. An ultrasonic sensor comprising:
a case having one end closed and the other end opened;
a piezoelectric element fixedly coupled to one end of an inner portion of the case;
a sound absorbing member coupled to an upper surface of the piezoelectric element so as to cover a portion of the piezoelectric element;
a conductive member having one end connected to the piezoelectric element and the other end connected to the sound absorbing member; and
a lead wire electrically coupled to the conductive member and the case.

2. The ultrasonic sensor as set forth in claim 1, wherein the conductive member includes:
a contact part electrically connected to the upper surface of the piezoelectric element; and
a lead wire connection part extended from the contact part and fixed to an upper portion of an outer peripheral surface of the sound absorbing member to thereby be electrically connected to the lead wire.

3. The ultrasonic sensor as set forth in claim 2, wherein the lead wire connection part includes a fixing groove part formed in order to be electrically connected to the lead wire.

4. The ultrasonic sensor as set forth in claim 1, wherein the conductive member is formed of any one of a conductive wire, a conductive rubber, and a conductive film.

5. The ultrasonic sensor as set forth in claim 1, wherein the sound absorbing member has a cylindrical shape in which it includes: a hollow hole formed in order to open a portion of the upper surface of the piezoelectric element to the outside; and a fixing groove part formed in an outer peripheral surface thereof so as to fix the lead wire in order to electrically connect the lead wire and an inner side surface of the case to each other.

6. The ultrasonic sensor as set forth in claim 1, wherein the case includes a reception groove formed in an inner side of the closed one end thereof so that the piezoelectric element is fixedly coupled thereto.

7. The ultrasonic sensor as set forth in claim 1, wherein the lead wire includes:
an anode (+) lead wire electrically coupled to the conductive member; and
a cathode (−) lead wire electrically coupled to an inner side wall surface of the case.

8. The ultrasonic sensor as set forth in claim 1, further comprising a filling member filled in the inner portion of the case in order to cover the piezoelectric element and the sound absorbing member from the outside and shield an ultrasonic wave generated from the piezoelectric element from moving toward the opened portion of the case.

9. A method of manufacturing an ultrasonic sensor, the method comprising:
(a) fixedly coupling a piezoelectric element to an inner portion of a case having a reception groove formed at an inner side of a closed one end thereof;
(b) coupling a cylindrical sound absorbing member having a fixing groove part formed in an outer peripheral surface thereof and a hollow hole formed in order to open a portion of an upper surface of the piezoelectric element to the upper surface of the piezoelectric element;
(c) fixedly coupling a conductive member to upper surfaces of the piezoelectric element and the sound absorbing member; and
(d) fixedly coupling a cathode (−) lead wire to the fixing groove part of the sound absorbing member and fixedly coupling an anode (+) lead wire to the conductive member.

10. The method as set forth in claim 9, further comprising, after step (d), filling a filling member in the inner portion of the case in order to cover the piezoelectric element and the sound absorbing member from the outside and shield an ultrasonic wave generated from the piezoelectric element from moving toward the opened portion of the case.
